(19) United States
(12) Patent Application Publication
(10) Pub. No.: US 2016/0276555 A1
(43) Pub. Date: Sep. 22, 2016

(54) LIGHT EMITTING DEVICE MANUFACTURING METHOD AND LIGHT EMITTING DEVICE

(71) Applicant: TOYODA GOSEI CO., LTD., Kiyosu-shi (JP)

(72) Inventors: Takayoshi YAJIMA, Kiyosu-shi (JP); Hiroshi ITO, Kiyosu-shi (JP)

(21) Appl. No.: 15/068,360

(22) Filed: Mar. 11, 2016

(30) Foreign Application Priority Data
Mar. 18, 2015 (JP) 2015-054981
Nov. 18, 2015 (JP) 2015-225613

(51) Int. Cl. H01L 33/56; H01L 33/62

(52) U.S. Cl. CPC H01L 33/56; H01L 33/62; H01L 2933/0033; H01L 2933/005; H01L 2933/0066

(57) ABSTRACT

A light emitting device manufacturing method includes: bonding a second film having an adhesive layer formed thereon to a substrate having bonded on a surface of a first film and transferring the adhesive layer onto the surface of the substrate; peeling off and removing the second film from the substrate; adhering and fixing a lead member to the adhesive layer; peeling off and removing the first film from the substrate; mounting a light emitting element on the lead member; and sealing the light emitting element and the lead member with a sealing material using a potting method to form a package.

### CROSS-REFERENCE TO RELATED APPLICATION(S)

This application is based upon and claims the benefit of priority from Japanese Patent Applications No. 2015-225613, filed on Nov. 18, 2015 and No. 2015-054981, filed on Mar. 18, 2015, the entire contents of which are incorporated herein by reference.

### BACKGROUND

1. Field of the Invention

The present invention relates to a light emitting device manufacturing method and a light emitting device.

2. Description of the Related Art

JP-A-2005-39129 discloses a light source device in which a flip-chip light-emitting diode (LED) element is mounted on a surface of a flexible printed circuit board and the flip-chip LED element is sealed by a light-transmitting sealing resin.

JP-T-2007-531303 discloses a semiconductor light emitting device in which a flexible film is formed on a surface of a substrate and a semiconductor light emitting element is formed between the substrate and the flexible film.

JP-A-2012-230967 discloses a light-emitting diode module in which a light-emitting diode element is mounted on a surface of an insulating substrate, a reflector as a surrounding member surrounding the light-emitting diode element is bonded onto the surface of the insulating substrate, the inside of the reflector is filled with a light-transmitting sealing material, and the light-emitting diode element is sealed by the sealing material.

JP-A-2012-230967 also discloses a light-emitting diode module in which a recessed portion is formed on the surface of an insulating substrate, a light-emitting diode element is mounted in the recessed portion, the recessed portion is filled with a light-emitting sealing material, and the light-emitting diode element is sealed by the sealing material.

In the technique described in JP-A-2005-39129, since the flexible printed circuit board with a high cost is used, there is a problem in that the manufacturing cost is high.

In the technique described in JP-T-2007-531303, since sealing performance of the flexible film is low, there is a problem in that the semiconductor light emitting element is likely to be exposed to steam or corrosive gas in the air or the like to cause malfunction.

In the technique using the reflector as a surrounding member in JP-A-2012-230967, there is a problem in that a mold with a high cost is required for manufacturing the reflector and thus the manufacturing cost is high.

In the technique of forming the recessed portion on the insulating substrate in JP-A-2012-230967, since the insulating substrate has to be etched to form the recessed portion, there is a problem in that etching equipment with a high cost is required and thus the manufacturing cost is high.

### SUMMARY

The present invention is made to solve the above-mentioned problems and has the following objects:

(1) to provide a method of manufacturing a light emitting device which is not likely to cause malfunction with a low cost; and

(2) to provide a light emitting device which is manufactured using the above-mentioned manufacturing method of (1).

According to a first aspect of the present invention, there is provided a light emitting device manufacturing method including: bonding a second film having an adhesive layer formed thereon to a substrate having bonded on a surface of a first film and transferring the adhesive layer onto the surface of the substrate; peeling off and removing the second film from the substrate; adhering and fixing a lead member to the adhesive layer; peeling off and removing the first film from the substrate; mounting a light emitting element on the lead member; and sealing the light emitting element and the lead member with a sealing material using a potting method to form a package.

According to the first aspect, since a light emitting device can be manufactured using simple light work indicated by the above and large-scale capital investment is not required for manufacturing the light emitting device, it is possible to reduce a manufacturing cost of a light emitting device.

According to the first aspect, when the sealing material is formed using the potting method, the sealing material does not easily leak outward from the outer circumferential edge of the substrate due to a surface tension along the outer circumferential edge of the substrate. Accordingly, it is not necessary to form a particular sealing material surrounding the substrate and it is possible to form a substantially dome-like sealing material on only the surface of the substrate.

According to the first aspect, since a high-cost flexible printed circuit board is not used, it is possible to reduce the manufacturing cost of a light emitting device.

According to the first aspect, since a flexible film is not used as the sealing material and the light emitting element and the lead member can be sealed with the sealing material formed using a potting method, it is possible to reliably seal the light emitting element and the lead member and to prevent the light emitting element from being exposed to steam or corrosive gas in the air or the like to cause malfunction. As a result, it is possible to provide a light emitting device which is not likely to cause malfunction.

According to the first aspect, since a reflector as a surrounding member is not used and a high-cost mold for manufacturing the reflector is not necessary, it is possible to reduce the manufacturing cost of a light emitting device.

A second aspect of the present invention provides the light emitting device manufacturing method according to the first aspect, wherein the adhesive layer is transferred onto the entire surface of the substrate.

According to the second aspect, the adhesive layer is formed on the entire surface of the substrate. Accordingly, even when the lead member is slightly misaligned from the substrate in adhering and fixing the lead member to the adhesive layer of the substrate, it is possible to reliably adhere and fix the lead member to the adhesive layer and it is not necessary to pay excessive attention to the misalignment, thereby enhancing workability.

A third aspect of the present invention provides the light emitting device manufacturing method according to the first aspect, wherein the adhesive layer is transferred to only a part, to which the lead member is adhered, on the surface of the substrate.

According to the third aspect, since the adhesive layer is formed only between the substrate and the lead member, it is possible to decrease an area of the adhesive layer in comparison with the second aspect and to decrease an amount of adhesive for forming the adhesive layer to reduce the material cost, thereby further reducing the manufacturing cost of a light emitting device.

A fourth aspect of the present invention provides the light emitting device manufacturing method according to the first aspect, wherein: an adhesive layer for the lead member and an adhesive layer for the sealing material are formed on the second film; and the adhesive layer for the lead member is transferred to a part, to which the lead member is adhered, on the surface of the substrate and transferring the adhesive layer for the sealing material to a part, to which the sealing material is adhered, on the surface of the substrate.

According to the fourth aspect, since the substrate and the sealing material can be reliably adhered and fixed to each other via the adhesive layer, it is possible to further enhance sealing performance of the sealing material.

A fifth aspect of the present invention provides the light emitting device manufacturing method according to any one of the first, third, and fourth aspects, wherein: a decorative layer in addition to the adhesive layer is formed on the second film; and the adhesive layer and the decorative layer are transferred onto the surface of the substrate.

According to the fifth aspect, it is possible to enhance a fine view of a light emitting device by forming the decorative layer.

According to the fifth aspect, since the decorative layer is transferred to the substrate in the same step as transferring the adhesive layer to the substrate, it is not necessary to add a step of forming the decorative layer and it is thus possible to prevent an increase in manufacturing cost of a light emitting device.

A sixth aspect of the present invention provides the light emitting device manufacturing method according to any one of the first, third, fourth, and fifth aspects, wherein: a masking layer not having adhesiveness to the sealing material in addition to the adhesive layer is formed on the second film; and the adhesive layer is transferred onto the surface of the substrate, and the masking layer is transferred onto an outer circumferential edge on the surface of the substrate.

According to the sixth aspect, in forming the sealing material using a potting method, it is possible to prevent the sealing material from passing over the masking layer to flow outward from the substrate by means of the masking layer formed on the outer circumferential edge of the substrate. Accordingly, it is possible to reliably secure the operational advantages of the first aspect.

A seventh aspect of the present invention provides the light emitting device manufacturing method according to any one of the first to sixth aspects, wherein: a plurality of the substrates are adhered to the first film; a plurality of the lead members are integrally formed with a single lead frame; and the light emitting device manufacturing method further includes segmenting a plurality of the packages by cutting the lead members from the lead frame.

According to the seventh aspect, since the plural packages can be simultaneously manufactured, it is possible to reduce the manufacturing cost of light emitting devices due to a scale merit.

According to an eighth aspect of the present invention, there is provided a light emitting device which is manufactured by the light emitting device manufacturing method according to the first aspect, wherein the adhesive layer is formed between the substrate and the lead member.

According to a ninth aspect of the present invention, there is provided a light emitting device which is manufactured by the light emitting device manufacturing method according to the second aspect, wherein the adhesive layer is formed on the entire surface of the substrate.

According to a tenth aspect of the present invention, there is provided a light emitting device which is manufactured by the light emitting device manufacturing method according to the third aspect, wherein the adhesive layer is formed only between the substrate and the lead member and the adhesive layer is not formed between the substrate and the sealing material.

According to an eleventh aspect of the present invention, there is provided a light emitting device which is manufactured by the light emitting device manufacturing method according to the fourth aspect, wherein the adhesive layer for the lead member is formed between the substrate and the lead member and the adhesive layer for the sealing member is formed between the substrate and the sealing member.

According to a twelfth aspect of the present invention, there is provided a light emitting device which is manufactured by the light emitting device manufacturing method according to the fifth aspect, wherein the decorative layer is formed on the surface of the substrate.

According to a thirteenth aspect of the present invention, there is provided a light emitting device which is manufactured by the light emitting device manufacturing method according to the sixth aspect, wherein the masking layer is formed on the outer circumferential edge on the surface of the substrate.

According to the eighth to thirteenth aspects, it is possible to obtain the same operational advantages as the operation advantages of the first to sixth aspects.

### BRIEF DESCRIPTION OF THE DRAWINGS

The present invention will become more fully understood from the detailed description given hereinbelow and the accompanying drawing which is given by way of illustration only, and thus is not limitative of the present invention and wherein:

FIGS. 1A to 1C are longitudinal cross-sectional views illustrating a method of manufacturing a light emitting device according to a first embodiment of the present invention;

FIG. 2A is a plan view illustrating the method of manufacturing a light emitting device;

FIG. 2B is a longitudinal cross-sectional view illustrating the method of manufacturing a light emitting device and is a perspective cross-sectional view taken along line X-X in FIG. 2A;

FIG. 3A is a plan view illustrating the method of manufacturing a light emitting device;

FIG. 3B is a longitudinal cross-sectional view illustrating the method of manufacturing a light emitting device and is a perspective cross-sectional view taken along line X-X in FIG. 2A;

FIG. 4A is a plan view illustrating the method of manufacturing a light emitting device;

FIGS. 4B and 4C are longitudinal cross-sectional views illustrating the method of manufacturing a light emitting device and are perspective cross-sectional views taken along line X-X in FIG. 4A;

FIG. 5A is a plan view illustrating the method of manufacturing a light emitting device;

FIG. 5B is a longitudinal cross-sectional view illustrating the method of manufacturing a light emitting device and is a perspective cross-sectional view taken along line X-X in FIG. 5A;

FIG. 6A is a plan view illustrating the method of manufacturing a light emitting device;

FIG. 6B is a longitudinal cross-sectional view illustrating the method of manufacturing a light emitting device and is a perspective cross-sectional view taken along line X-X in FIG. 6A;

FIG. 7A is a plan view of a light emitting device;

FIG. 7B is a longitudinal cross-sectional view of the light emitting device and is a perspective cross-sectional view taken along line X-X in FIG. 7A;

FIG. 8 is a cross-sectional view illustrating a configuration of a light emitting device according to another embodiment of the present invention;

FIG. 9 is a cross-sectional view illustrating a configuration of a light emitting device according to another embodiment of the present invention;

FIG. 10A is a plan view illustrating a method of manufacturing a light emitting device according to a second embodiment of the present invention;

FIG. 10B is a longitudinal cross-sectional view of the light emitting device and is a cross-sectional view corresponding to a perspective cross-section taken along line X-X in FIG. 10A;

FIG. 10C is a longitudinal cross-sectional view of the light emitting device and is a cross-sectional view corresponding to a perspective cross-section taken along line Y-Y in FIG. 10A;

FIG. 11A is a plan view illustrating a method of manufacturing a light emitting device according to a third embodiment of the present invention;

FIG. 11B is a longitudinal cross-sectional view illustrating the light emitting device and is a cross-sectional view corresponding to a perspective cross-section taken along line X-X in FIG. 11A;

FIG. 11C is a longitudinal cross-sectional view of the light emitting device and is a cross-sectional view corresponding to a cross-section corresponding to a perspective cross-section taken along line Y-Y in FIG. 11A;

FIG. 12A is a plan view illustrating a method of manufacturing a light emitting device according to a fourth embodiment of the present invention;

FIG. 12B is a plan view of the light emitting device;

FIG. 13A is a plan view illustrating a method of manufacturing a light emitting device according to a fifth embodiment of the present invention;

FIG. 13B is a longitudinal cross-sectional view illustrating the light emitting device and is a cross-sectional view corresponding to a perspective cross-section taken along line X-X in FIG. 13A; and

FIG. 13C is a longitudinal cross-sectional view of the light emitting device and is a cross-sectional view corresponding to a cross-section corresponding to a perspective cross-section taken along line Y-Y in FIG. 13A.

### DETAILED DESCRIPTION OF THE INVENTION

Hereinafter, embodiments of the present invention will be described with reference to the accompanying drawings. In the embodiments, the same constituent members and elements will be referenced by the same reference signs and description thereof will not be repeated.

In the drawings, numerical values, shapes, and formation spots of the constituent members of the embodiments are exaggerated and schematically illustrated for the purpose of easy understanding, and the dimensions, shapes, and formation spots of the constituent members may not match actual constituent members.

### First Embodiment

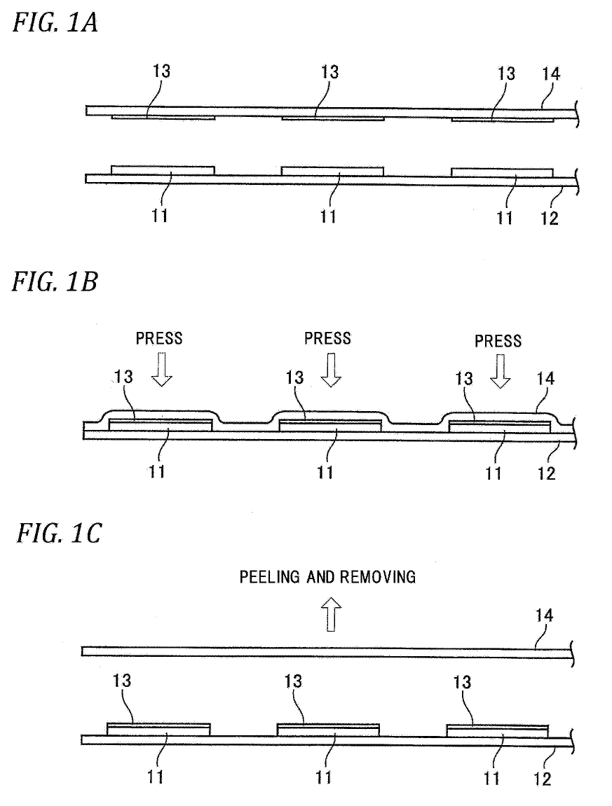

A method of manufacturing a light-emitting device 10 according to a first embodiment of the present invention will be described below with reference to FIGS. 1A to 7.

First Step: First, as illustrated in FIG. 1A, a first film (mount) 12 having plural substrates 11 bonded to the surface thereof and a second film 14 having plural adhesive layers 13 are formed on one side are prepared, and the films 12 and 14 are disposed to be parallel to each other such that the substrates 11 and the adhesive layers 13 face each other.

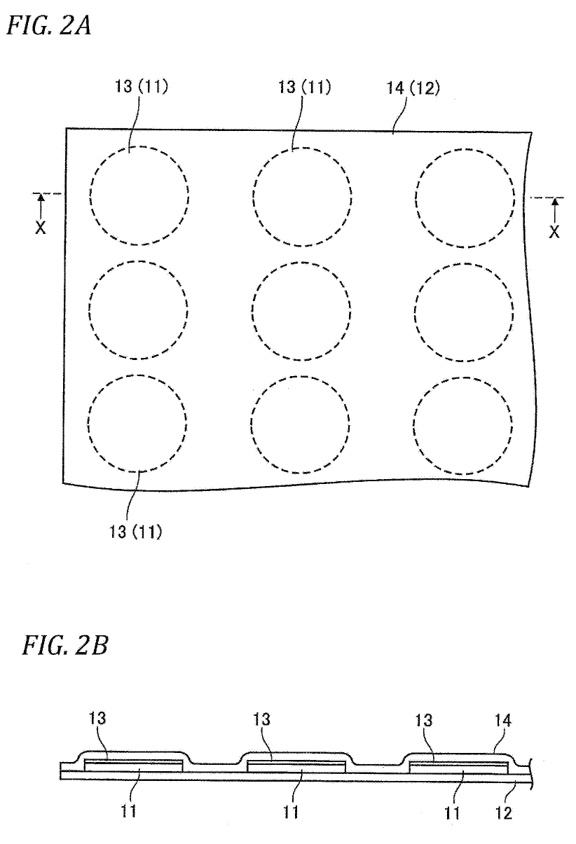

As illustrated in FIG. 2A, the substrates 11 and the adhesive layers 13 are formed in a circular shape having the same dimension and shape in a plan view, and the substrates 11 and the adhesive layers 13 are regularly arranged in parallel in the horizontal and vertical directions on the films 12 and 14, respectively.

The substrate (base member) 11 is formed of a thin plate member of, for example, a synthetic resin material (such as PP (PolyPropylene), TPO (Thermo PolyOlefin), PVC (PolyVinyl Chloride), PC (PolyCarbonate), PMMA (PolyMethylMethacrylate), COP (Cyclo Olefin Polymer), or ABS (Acrylonitrile-Butadiene-Styrene resin)) having satisfactory heat resistance, a metal material (such as an aluminum alloy or a copper alloy), or a ceramic material (such as alumina, aluminum nitride, or silicon nitride).

The films 12 and 14 is formed of a thin film of a synthetic resin material (such as PET (Poly Ethylene Terephthalate), PE (PolyEthylene), polyurethane, or PMMA) having satisfactory flexibility.

The adhesive layers 13 are formed of various adhesives having satisfactory heat transmission for rapidly dissipating heat generated from LED chips 18 to the lead members 15 and 16 and satisfactory adhesiveness to the substrates 11 and the lead members 15 and 16.

In order to easily peel off the first film 12 from the substrates 11, the substrates 11 are temporarily fixed to the first film 12, for example, using pressing, an adhesive, or a double-sided tape.

The adhesive layers 13 are printed on the second film (a base film, a support film, or a carrier film) 14 having satisfactory peeling performance using various printing methods (such as a screen printing method, a pad printing method, and a doctor coating method).

As illustrated in FIG. 1B and FIGS. 2A and 2B, by superimposing the second film 14 on the first film 12 such that the substrates 11 and the adhesive layers 13 overlap without causing misalignment and pressing the surface (the opposite surface of the surface on which the adhesive layers 13 are formed) side of the second film 14, the substrates 11 and the adhesive layers 13 are pressed in a closely adhered state to transfer the adhesive layers 13 onto the surfaces of the substrates 11.

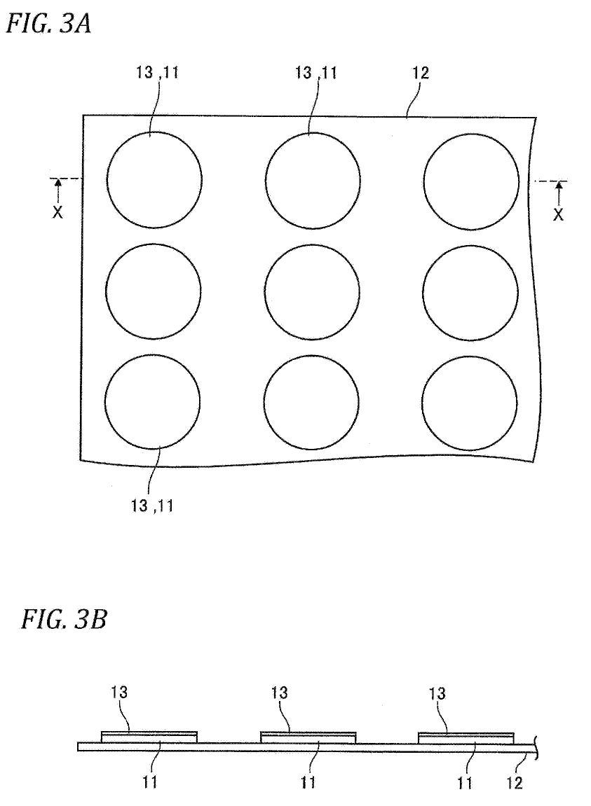

Second Step: As illustrated in FIG. 1C and FIGS. 3A and 3B, the second film 14 is peeled off and removed from the substrates 11 and the first film 12.

Then, the adhesive layers 13 are transferred onto the surface of the substrates 11 and remains thereon and only the second film 14 is removed.

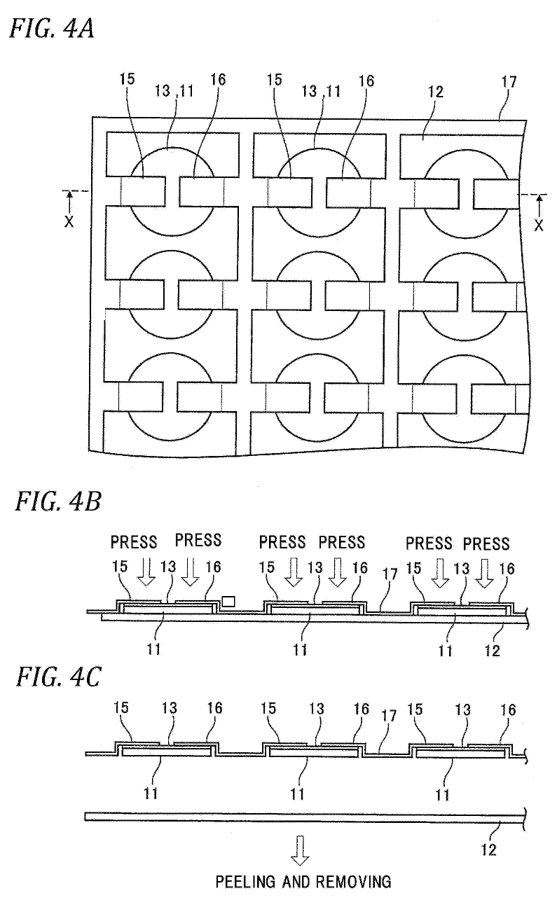

Third Step: As illustrated in FIGS. 4A and 4B, by preparing a lead frame 17 in which plural pairs of lead members 15 and 16 are integrally formed, superimposing the lead frame 17 on the first film 12 such that the adhesive layers 13 and the lead members 15 and 16 overlap without causing misalignment, and pressing the surface (the opposite surface of the surface in contact with the adhesive layers 13) side of the lead members 15 and 16, the adhesive layers 13 and the lead members 15 and 16 are pressed in a closely adhered state to adhere and fix the adhesive layers 13 and the lead members 15 and 16 to each other.

Fourth Step: As illustrated in FIG. 4C, the first film 12 is peeled off and removed from the substrates 12.

At this time, since the substrates 11 are adhered and fixed to the lead members 15 and 16 with the adhesive layers 13, the substrates 11 are held by the lead frame 17 without being detached.

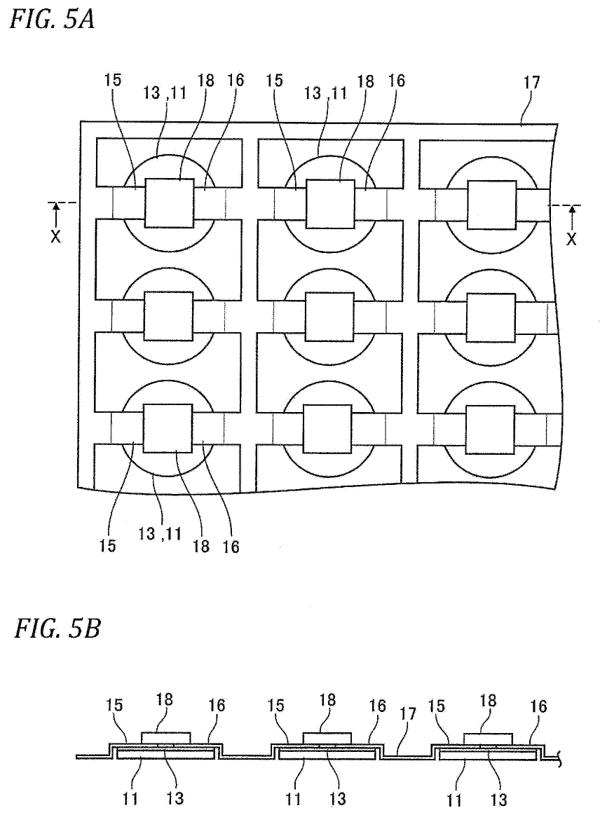

Fifth Step: As illustrated in FIGS. 5A and 5B, LED chips 18 are face-down-mounted (flip-chip-mounted) on the lead members 15 and 16 using bumps (not illustrated) to electrically and mechanically connect the lead members 15 and 16 to the LED chips 18.

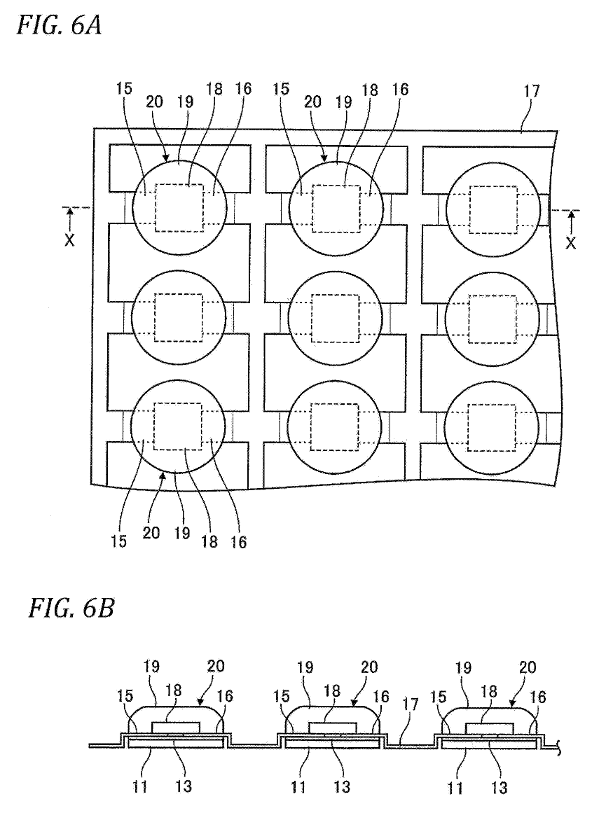

Sixth Step: As illustrated in FIGS. 6A and 6B, plural packages 20 are formed by sealing the LED chips 18 and the lead members 15 and 16 with a sealing material 19 using a potting (dispensing) method and then curing the sealing material 19.

The sealing material 19 is formed of a synthetic resin material (such as a silicone-based resin or an epoxy-based resin) which is liquid which can be dropped in the potting method at the room temperature, which is curable (such as ultraviolet-curable, heat-curable, room-temperature-curable, or two-liquid-mixed-curable), and which has satisfactory transparency after being cured.

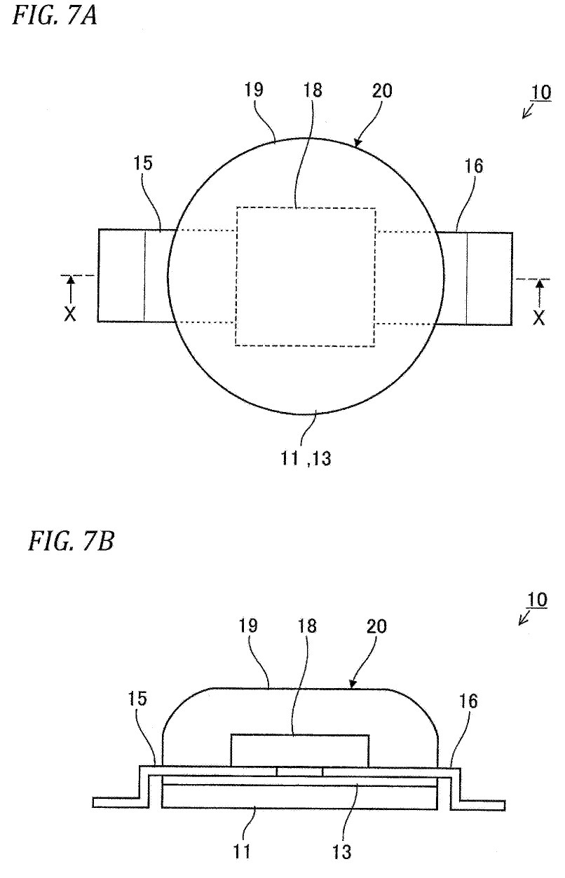

Seventh Step: By cutting out the lead members 15 and 16 from the lead frame 17 illustrated in FIGS. 6A and 6B, the packages 20 are segmented as illustrated in FIGS. 7A and 7B.

As illustrated in FIGS. 7A and 7B, in the light emitting device 10 according to the first embodiment, the adhesive layer 13 is formed between the substrate 11 and the lead members 15 and 16, and the adhesive layer 13 is formed on the entire surface of the substrate 11.

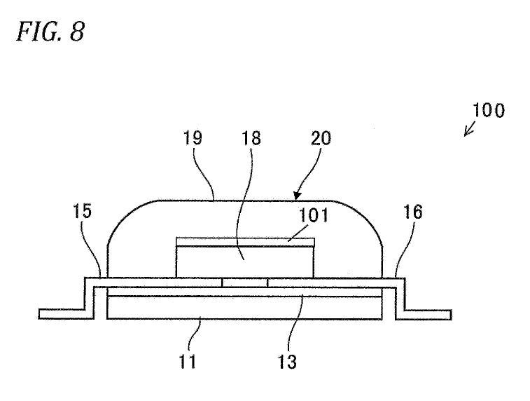

As illustrated in FIG. 8, a fluorescent layer 101 can be stacked on the top surface of the LED chip 18 of the flip-chip mounting type. In FIG. 8, the same elements as illustrated in FIGS. 7A and 7B are referenced by the same reference numerals and description thereof will not be partially repeated.

An emission color of a light emitting device 110 can be controlled by combination of an emission wavelength of the LED 18 and fluorescent substrate included in the fluorescent layer 101.

The fluorescent layer 101 may be formed between the fifth step and the sixth step (forming method: potting method), or the fluorescent layer may be formed on the top surface of the LED chip 18 in advance and the LED chip 18 may be mounted in the fifth step.

The fluorescent layer 101 is obtained by dispersing fluorescent particles in a heat-resistance resin matrix (a silicon resin or an epoxy resin), and the thickness thereof can be designed arbitrarily and can be set to, for example, 50 μm to 200 μm. The dispersed fluorescent particles can be arbitrarily selected depending on the application of the light emitting device 110. Plural types of fluorescent substance may be used together. In this case, the fluorescent layer 101 can be formed to have a multilayer structure and different fluorescent particles can be dispersed in the respective layers.

Similarly, fluorescent particles may be dispersed in the sealing material 19.

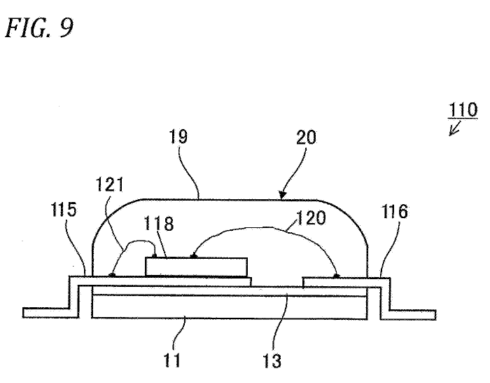

FIG. 9 illustrates another type of light emitting device 120. The same elements as illustrated in FIGS. 7A and 7B are referenced by the same reference numerals and description thereof is not partially repeated. In the light emitting device 120, an LED chip 118 of a face-up mounting type is employed and is mounted on one lead member 115. One electrode of the LED chip 118 is electrically connected to the other lead member 116 via a wire 120. The other electrode of the LED chip 118 is electrically connected to the lead member 115 via a wire 121.

In the light emitting device 120 illustrated in FIG. 9, the bottom surface of the LED chip 118 is fixed to one lead member 115 in the fifth step, and then the wires 120 and 121 are suspended between the LED chip 118 and the lead members 115 and 116. Thereafter, the sixth step is performed to form the sealing member 19.

Fluorescent particles can be dispersed in the sealing material 19. The material of the fluorescent particles to be dispersed can be appropriately selected depending on the application of the light emitting device 120.

### Operational Advantages of First Embodiment

According to the first embodiment, the following operational advantages can be obtained.

(1) In the first embodiment, the light emitting device 10 can be manufactured by simple light work of adhering the second film 14 having the adhesive layers 13 formed thereon to the first film 12 having the substrates 11 bonded thereto, peeling off the second film 14, adhering the lead members 15 and 16 of the lead frame 17 to the adhesive layers 13, and peeling off the first film 12. In addition, since large-scale capital investment is not required for manufacturing the light emitting device 10, it is possible to reduce a manufacturing cost of the light emitting device 10.

(2) According to the first embodiment, in the first step illustrated in FIGS. 1A and 1B and FIGS. 2A and 2B, since the adhesive layers 13 are transferred onto the entire surfaces of the substrates 11, the adhesive layers 13 are formed on the entire surfaces of the substrates 11.

Accordingly, even when the lead members 15 and 16 are slightly misaligned from the substrates 11 in adhering and fixing the lead members 15 and 16 to the adhesive layers 13 of the substrates 11 in the third step illustrated in FIGS. 4A and 4B, it is possible to reliably adhere and fix the lead members 15 and 16 to the adhesive layers 13 and it is not necessary to pay excessive attention to the misalignment, thereby enhancing workability.

By dispersing fine particles of a material having high light reflectance (such as alumina or titanium oxide) in the adhesive layer 13, it is possible to enhance the light reflectance of the surface of each substrate 11 and thus to improve emission efficiency of the light emitting device 10.

(3) In the sixth step illustrated in FIGS. 6A and 6B, when the sealing material 19 is formed using the potting method, the sealing material 19 does not easily leak outward from the outer circumferential edge of the substrate 11 due to a surface tension along the outer circumferential edge of the substrate 11. Accordingly, it is not necessary to form a particular sealing frame material surrounding the substrate 11 and it is possible to form a substantially dome-like sealing material 19 on only the surface of the substrate 11.

(4) According to the first embodiment, unlike the technique described in JP-A-2005-39129, since a high-cost flexible printed circuit board is not used, it is possible to reduce the manufacturing cost of the light emitting device 10.

According to the first embodiment, unlike the technique described in JP-T-2007-531303, since a flexible film is not used as the sealing material and the LED chip 18 and the lead members 15 and 16 are sealed with the sealing material 19 formed using the potting method, it is possible to reliably seal the LED chip 18 and the lead members 15 and 16 and to prevent the LED chip 18 from being exposed to steam or corrosive gas in the air or the like to cause malfunction. As a result, it is possible to provide the light emitting device 10 which is not likely to cause malfunction.

(6) According to the first embodiment, unlike the technique described in JP-A-2012-230967, since a reflector as a surrounding member is not used and a high-cost mold for manufacturing the reflector is not necessary, it is possible to reduce the manufacturing cost of the light emitting device 10.

According to the first embodiment, unlike the technique described in JP-A-2012-230967, since a recessed portion is not formed on an insulating substrate and thus high-cost etching equipment for forming the recessed portion is not necessary, it is possible to reduce the manufacturing cost of the light emitting device 10.

(7) According to the first embodiment, since the plural packages 20 can be simultaneously manufactured, it is possible to reduce the manufacturing cost of the light emitting devices 10 due to a scale merit.

(8) According to the first embodiment, in the first step illustrated in FIGS. 1A to 1C and FIGS. 2A and 2B, since the second film 14 having the adhesive layers 13 formed thereon are bonded to the substrates 11 adhered to the surface of the first film 12 and the adhesive layers 13 are transferred onto the surfaces of the substrates 11, it is possible to reliably and easily form the adhesive layers 13 on the surfaces of the substrates 11.

The adhesive layers 13 may be printed on the surfaces of the substrates 11 using various printing methods (such as a screen printing method, a pad printing method, and a coating method).

In this case, a printer dedicated for forming the adhesive layers 13 on the surfaces of the substrates 11 needs to be introduced into the manufacturing process of the light emitting device 10 and thus the manufacturing cost of the light emitting device 10 increases.

When the adhesive layers 13 are printed on the surface of the substrates 11, the second film 14 is not necessary.

The first film 12 having plural substrates 11 bonded thereto and the second film 14 having plural adhesive layers 13 formed thereon may be manufactured by a maker of the light emitting device 10, or may be delivered from a maker of a film material to the maker of the light emitting device 10. In this case, it is possible to greatly reduce the manufacturing cost of the light emitting device 10.

(9) According to the first embodiment, in the fourth step illustrated in FIG. 4C, the first film 12 is peeled off and removed from the substrates 11.

In the sixth step illustrated in FIGS. 6A and 6B, the first film 12 may be peeled off and removed from the substrates 11 after the LED chips 18 and the lead members 15 and 16 are sealed with the sealing material 19 to form plural packages 20.

However, in this case, in the fifth step illustrated in FIGS. 5A and 5B, the first film 12 does not have to be affected by heat, ultrasonic waves, pressure, and the like which are used to mount the LED chips 18 on the lead members 15 and 16.

That is, in the fifth step illustrated in FIGS. 5A and 5B, it is preferable that the first film 12 not be formed when the LED chips 18 are mounted on the lead members 15 and 16.

For example, when face-up mounting using potting wires is employed to mount the LED chips 18 on the lead members 15 and 16 and the potting wires are connected using heat, the high-cost first film 12 having high heat resistance is necessary.

When face-down mounting using bumps are employed to mount the LED chips 18 on the lead members 15 and 16 and the bumps are connected by ultrasonic bonding, the applied ultrasonic waves may leak to the first film 12 and may not reliably connect the bumps.

### Second Embodiment

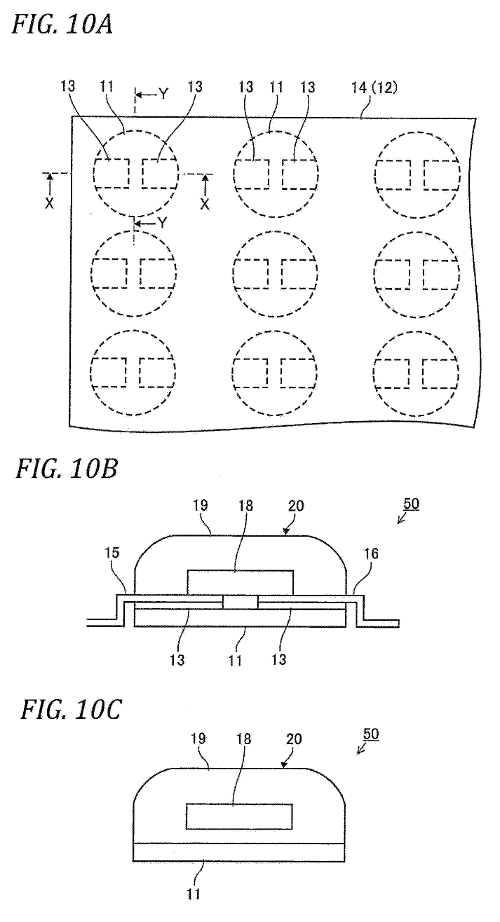

As illustrated in FIG. 10A, in a second embodiment of the present invention, the adhesive layers 13 of the second film 14 are formed in only positions corresponding to the adhering portions of the lead members 15 and 16 to the substrates 11 which are circular in a plan view.

Accordingly, in the first step of the second embodiment, the adhesive layers 13 are transferred to only the adhering portions of the lead members 15 and 16 on the surfaces of the substrates 11.

In a light emitting device 50 according to the second embodiment, the adhesive layer 13 is formed only between the substrate 11 and the lead members 15 and 16 as illustrated in FIG. 10B, and the adhesive layer 13 is not formed between the substrate 11 and the sealing material 19 as illustrated in FIG. 10C.

Accordingly, according to the second embodiment, it is possible to achieve the same operational advantages as the operational advantages (1) and (3) to (7) in the first embodiment.

According to the second embodiment, since the adhesive layers 13 of the second film 14 are formed at only the positions corresponding to the adhering portions of the lead members 15 and 16, it is possible to decrease an area of the adhesive layers 13 in comparison with the first embodiment (see FIGS. 2A and 10A) and to decrease an amount of adhesive for forming the adhesive layers 13 to reduce the material cost, thereby further reducing the manufacturing cost of the light emitting device 50.

In the third step illustrated in FIGS. 4A and 4B, even when the lead members 15 and 16 are slightly misaligned from the substrates 11 in adhering and fixing the lead members 15 and 16 to the adhesive layers 13 of the substrates 11, a margin of the misalignment may be predicted and the adhesive layers 13 of the second film 14 may be formed in parts wider by the margin than the adhering portions of the lead members 15 and 16 so as to reliably adhere and fix the lead members 15 and 16 to the adhesive layers 13.

### Third Embodiment

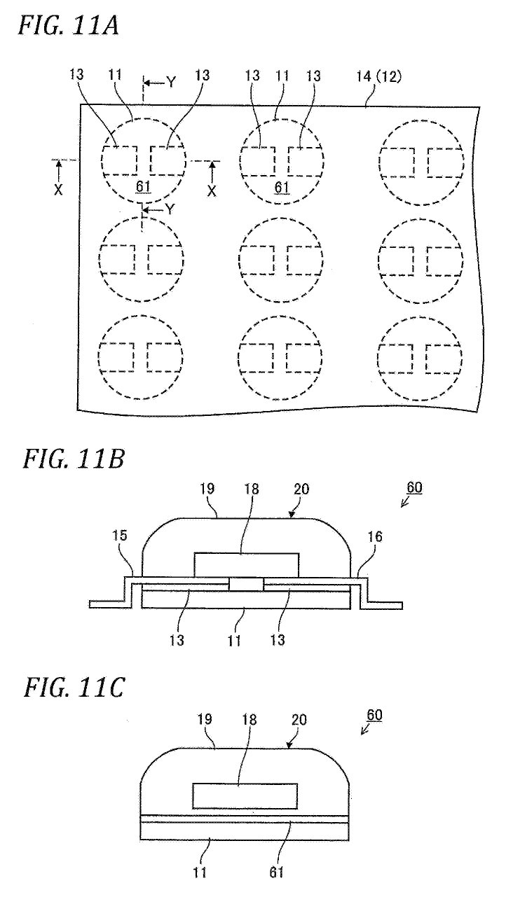

As illustrated in FIG. 11A, a lead-member adhesive layer 13 and a sealing-material adhesive layer 61 are formed on the second film 14 in a third embodiment of the present invention.

The lead-member adhesive layers 13 in the second film 14 are formed at only the positions corresponding to the adhering portions of the lead members 15 and 16, similarly to the adhesive layers 13 in the second embodiment.

The sealing-material adhesive layers 61 in the second film 14 are formed at only the positions corresponding to the adhering portions of the sealing materials 19.

The sealing-material adhesive layers 61 are formed of various adhesives having satisfactory adhesiveness to the substrates 11 and the sealing materials 19.

Accordingly, in the first step of the third embodiment, the lead-member adhesive layers 13 are transferred to the adhering portions of the lead members 15 and 16 on the surfaces of the substrates 11, and the sealing-material adhesive layers 61 are transferred to the adhering portions of the sealing materials 19 on the surface of the substrates 11.

In a light emitting device 60 according to the third embodiment, the lead-member adhesive layer 13 is formed between the substrate 11 and the lead members 15 and 16 as illustrated in FIG. 11B, and the sealing-material adhesive layer 61 is formed between the substrate 11 and the sealing material 19 as illustrated in FIG. 11C.

Accordingly, according to the third embodiment, it is possible to achieve the same operational advantages as the operational advantages (1) and (3) to (7) in the first embodiment.

According to the third embodiment, since the substrates 11 and the sealing materials 19 can be reliably adhered and fixed to each other using the sealing-material adhesive layers 61, it is possible to further enhance sealing performance of the sealing material 19 in comparison with the first embodiment.

### Fourth Embodiment

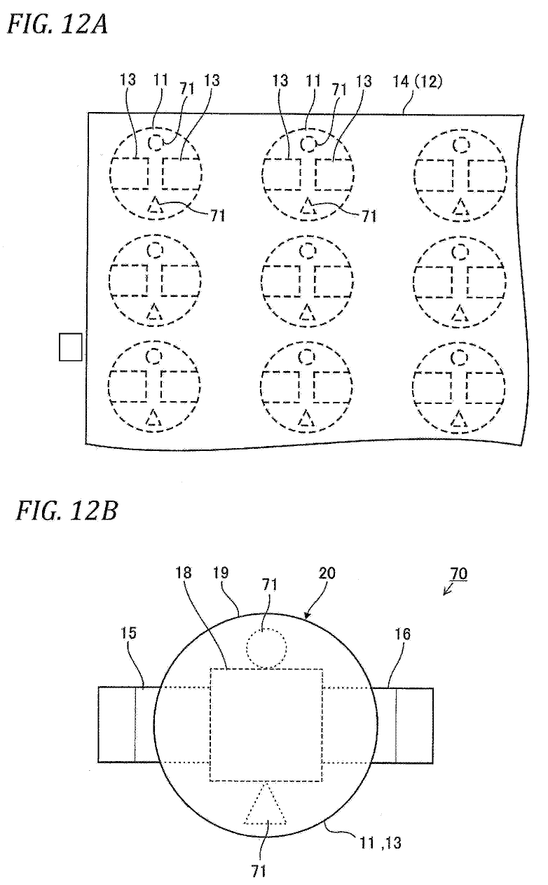

As illustrated in FIG. 12A, a decorative layer 71 in addition to the adhesive layers 13 is formed on the second film 14 of a fourth embodiment.

The adhesive layers 13 in the second film 14 are formed at only the positions corresponding to the adhering portions of the lead members 15 and 16, similarly to the adhesive layers 13 of the second embodiment.

The decorative layers 71 are formed of various adhesives having satisfactory adhesiveness to the substrates 11 and the sealing materials 19 and various pigments added to the adhesive.

Accordingly, in the first step of the fourth embodiment, the adhesive layers 13 are transferred onto the adhering portions of the lead members 15 and 16 on the surfaces of the substrates 11 and the decorative layers 71 are transferred onto the surfaces of the substrates 11.

As illustrated in FIG. 12B, in a light emitting device 70 according to the fourth embodiment, the decorative layer 71 is formed on the surface of the substrate 11.

Accordingly, according to the fourth embodiment, it is possible to achieve the same operational advantages as the operational advantages (1) and (3) to (7) in the first embodiment.

According to the fourth embodiment, it is possible to improve a fine view of the light emitting device 70 by forming the decorative layer 71.

According to the fourth embodiment, since the decorative layers 71 are transferred to the substrates 11 in the same step as transferring the adhesive layers 13 to the substrates 11, it is not necessary to add a step of forming the decorative layers 71 and it is thus possible to prevent an increase in manufacturing cost of the light emitting device 70.

The decorative layers 71 in the second film 14 form figures such as “O” and “Δ” in the example illustrated in FIGS. 12A and 12B, but any character, symbol, or figure may be formed.

### Fifth Embodiment

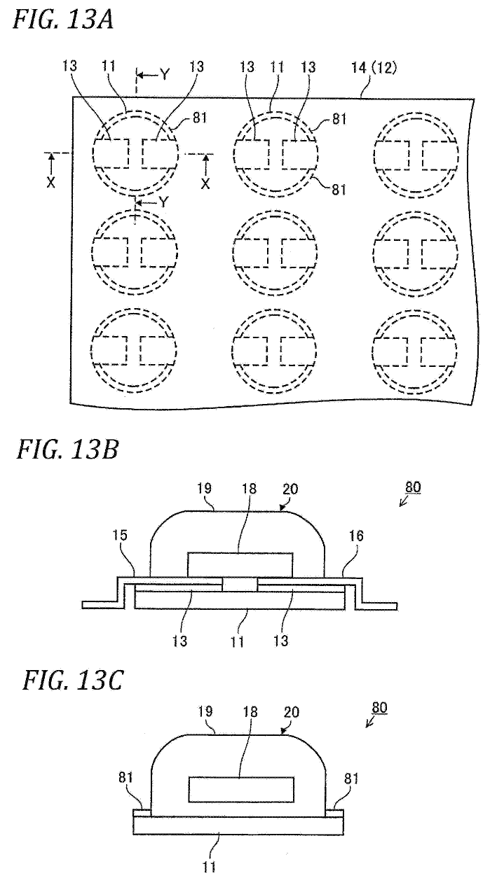

As illustrated in FIG. 13A, masking layers (non-adhesive layer) 81 not having adhesiveness to the sealing materials 19 in addition to the adhesive layers 13 are formed on the second film 14 of a fifth embodiment of the present invention.

The masking layers 81 in the second film 14 are formed at only the positions corresponding to the outer circumferential edges on the surfaces of the substrates 11.

Accordingly, in the first step of the fifth embodiment, the adhesive layers 13 are transferred onto the surfaces of the substrates 11 and the masking layers 81 are also transferred to the outer circumferential edges on the surfaces of the substrates 11.

As illustrated in FIG. 13C, in a light emitting device 80 according to the fifth embodiment, the masking layer 81 is formed on the outer circumferential edge on the surface of the substrate 11.

Therefore, according to the fifth embodiment, it is possible to achieve the same operational advantages as in the first embodiment.

According to the fifth embodiment, in forming the sealing materials 19 using the potting method in the sixth step illustrated in FIGS. 6A and 6B, it is possible to prevent the sealing materials 19 from passing over the masking layers 81 to flow outward from the substrates 11 by means of the masking layers 81 formed on the outer circumferential edges of the substrates 11. Accordingly, it is possible to further reliably achieve the operational advantage (3) in the first embodiment.

### Other Embodiments

The present invention is not limited to the above-mentioned embodiments, but may be modified in various forms. In this case, it is possible to achieve the same or better operations advantages as the operational advantages in the above-mentioned embodiments.

(A) The planar shape of each substrate 11 is circular in the above-mentioned embodiments, but the planar shape of each substrate 11 is not limited to a circular shape but may have nay shape.

(B) The LED chip 18 may be replaced with any semiconductor light emitting element (for example, an electroluminescence (EL) element).

(C) The above-mentioned embodiments may be appropriately combined. In this case, the operational advantages of the combined embodiments may be achieved or a synergy effect may be achieved.

The present invention is not limited to the above-mentioned aspects and the above-mentioned embodiments. Various modifications which can be easily thought out by those skilled in the art without departing from the scope of the appended claims are included in the present invention. Details of the publications explicitly described therein are assumed to be cited by reference herein in its entirety.

What is claimed is:

1. A light emitting device manufacturing method comprising:
bonding a second film having an adhesive layer formed thereon to a substrate having bonded on a surface of a first film and transferring the adhesive layer onto the surface of the substrate;
peeling off and removing the second film from the substrate;
adhering and fixing a lead member to the adhesive layer;
peeling off and removing the first film from the substrate;
mounting a light emitting element on the lead member; and
sealing the light emitting element and the lead member with a sealing material using a potting method to form a package.

2. The light emitting device manufacturing method according to claim 1, wherein
the adhesive layer is transferred onto the entire surface of the substrate.

3. The light emitting device manufacturing method according to claim 1, wherein
the adhesive layer is transferred to only a part, to which the lead member is adhered, on the surface of the substrate.

4. The light emitting device manufacturing method according to claim 1, wherein:
an adhesive layer for the lead member and an adhesive layer for the sealing material are formed on the second film; and
the adhesive layer for the lead member is transferred to a part, to which the lead member is adhered, on the surface of the substrate and transferring the adhesive layer for the sealing material to a part, to which the sealing material is adhered, on the surface of the substrate.

5. The light emitting device manufacturing method according to claim 1, wherein:
a decorative layer in addition to the adhesive layer is formed on the second film; and
the adhesive layer and the decorative layer are transferred onto the surface of the substrate.

6. The light emitting device manufacturing method according to claim 1, wherein:
a masking layer not having adhesiveness to the sealing material in addition to the adhesive layer is formed on the second film; and
the adhesive layer is transferred onto the surface of the substrate, and the masking layer is transferred onto an outer circumferential edge on the surface of the substrate.

7. The light emitting device manufacturing method according to claim 1, wherein:
a plurality of the substrates are adhered to the first film;
a plurality of the lead members are integrally formed with a single lead frame; and
the light emitting device manufacturing method further comprises segmenting a plurality of the packages by cutting the lead members from the lead frame.

8. A light emitting device which is manufactured by the light emitting device manufacturing method according to claim 1, wherein
the adhesive layer is formed between the substrate and the lead member.

9. A light emitting device which is manufactured by the light emitting device manufacturing method according to claim 2, wherein
the adhesive layer is formed on the entire surface of the substrate.

10. A light emitting device which is manufactured by the light emitting device manufacturing method according to claim 3, wherein
the adhesive layer is formed only between the substrate and the lead member and the adhesive layer is not formed between the substrate and the sealing material.

11. A light emitting device which is manufactured by the light emitting device manufacturing method according to claim 4, wherein
the adhesive layer for the lead member is formed between the substrate and the lead member, and the adhesive layer for the sealing member is formed between the substrate and the sealing member.

12. A light emitting device which is manufactured by the light emitting device manufacturing method according to claim 5, wherein
the decorative layer is formed on the surface of the substrate.

13. A light emitting device which is manufactured by the light emitting device manufacturing method according to claim 6, wherein
the masking layer is formed on the outer circumferential edge on the surface of the substrate.
